(19) United States
(12) Patent Application Publication
(10) Pub. No.: US 2006/0070768 A1
(43) Pub. Date: Apr. 6, 2006

(54) Printed circuit board assembly

(76) Inventor: Seung-eon Lee, Suwon-si (KR)

Correspondence Address: STANZIONE & KIM, LLP, 919 18TH STREET, N.W., SUITE 440, WASHINGTON, DC, 20006, US

(21) Appl. No.: 11/222,098

(22) Filed: Sep. 9, 2005

(30) Foreign Application Priority Data
Oct. 5, 2004 (KR) 2004-79136

(51) Int. Cl. H05K 7/06

(52) U.S. Cl. 174/250; 361/784

(57) ABSTRACT

A PCB assembly includes a main PCB having an accommodating slit part penetratingly formed therethrough and at least one main terminal part disposed at sides of the accommodating slit part, and a sub PCB having an inserting part which is insertable into the accommodating slit part, the sub PCB including a sub terminal part disposed to correspond to the main terminal part, and a through slot formed in the inserting part along an inserting direction of the sub PCB. Accordingly, the PCB assembly stably combines the sub PCB and the main PCB.

### CROSS-REFERENCE TO RELATED APPLICATIONS

This application claims the benefit under 35 U.S.C. § 119 of Korean Patent Application No. 2004-79136, filed on Oct. 5, 2004, in the Korean Intellectual Property Office, the disclosure of which is incorporated herein in its entirety by reference.

### BACKGROUND OF THE INVENTION

1. Field of the Invention

The present general inventive concept relates to a printed circuit board (PCB) assembly including a main PCB and a sub PCB, and more particularly, to a PCB assembly which has an improved structure to combine a main PCB and a sub PCB.

2. Description of the Related Art

FIG. 1 illustrates a side sectional view of a conventional PCB assembly, and FIG. 2 illustrates a side sectional view of a conventional PCB assembly combined by a pin connector.

Generally, there are two ways to manufacture the PCB assembly 101 by combining a sub PCB 120 and a main PCB 110. One is to directly connect the sub PCB 120 and the main PCB 110 by soldering (see FIG. 1). The other is to adhere the sub PCB 120 to the main PCB 110 with the pin connector 128 by soldering (see FIG. 2).

As illustrated in FIG. 1, in the conventional PCB assembly 101, solder-lands 116 and 126 are formed at a combination part of the main PCB 110 and the sub PCB 120, and soldering is performed on the solder-lands 116 and 126. The soldering is performed on the rear surface of the main PCB 110 which is combined with the sub PCB 120. In case that melted soldering flux provided to the rear surface of the main PCB 110 is insufficient, a soldered part 130 is used which can be separated from the solder-lands 116 and 126. However, the combining force of the soldered part 130 becomes weakened by vibrations of the sub PCB 120.

To overcome the disadvantage that the combination of the main PCB 110 and the sub PCB 120 has a low degree of vibration tolerance, in the conventional PCB assembly 101, the rear surface of the main PCB 110 is soldered under the condition that the sub PCB 120 is combined with the main PCB 110 by the pin connector 128, as illustrated in FIG. 2. However, therein lies a problem that the sub PCB 120 tilts with respect to the main PCB 110 while fixing the pin connector 128 in position. Also, an additional process is required to fix the pin connector 128 on the sub PCB 120.

### SUMMARY OF THE INVENTION

Accordingly, the present general inventive concept provides a PCB assembly having a stable combination of a sub PCB and a main PCB.

Additional aspects of the present general inventive concept will be set forth in part in the description which follows and, in part, will be obvious from the description, or may be learned by practice of the general inventive concept.

The foregoing and/or other aspects of the present general inventive concept are achieved by providing a PCB assembly comprising a main PCB having an accommodating slit part penetratingly formed therethrough and at least one main terminal part disposed at sides of the accommodating slit part, and a sub PCB having an inserting part which is insertable into the accommodating slit part, the sub PCB comprising at least one sub terminal part disposed to correspond to the at least one main terminal part, and a through slot formed in the inserting part along an inserting direction of the sub PCB.

The through slot may be longer than a thickness of the main PCB, and may extend through the accommodating slit part.

The foregoing and/or other aspects of the present general inventive concept are also achieved by providing a printed circuit board (PCB) assembly, comprising a main PCB having an accommodating hole formed through first and second surfaces thereof, and a sub PCB having an inserting portion insertable into the main PCB and one or more through holes provided through the inserting portion to transfer melted soldering flux from the first surface of the main PCB to the second surface of the main PCB when the inserting portion is inserted into the accommodating hole to fix the sub PCB to the main PCB.

The foregoing and/or other aspects of the present general inventive concept are also achieved by providing a printed circuit board (PCB) assembly, comprising a main PCB having an accommodating slit formed through first and second surfaces thereof and a plurality of main terminals surrounding the accommodating slit on the first and second surfaces, and a sub PCB insertable into the accommodating slit and having a plurality of sub terminals to form a plurality of electrical connections with the plurality of main terminals and a through hole to receive melted soldering flux at one of the electrical connections and to spread the received melted soldering flux to the remaining electrical connections to fix the sub PCB to the main PCB at each of the electrical connections.

The foregoing and/or other aspects and advantages of the present general inventive concept are also achieved by providing a method of fixing a sub PCB to a main PCB, comprising inserting a portion of the sub PCB through an accommodating slit formed in the main PCB, receiving melted soldering flux at a first surface of the main PCB to fix the sub PCB to the first surface of the main PCB, and spreading the melted soldering flux along a through hole formed in the sub PCB to a second surface of the main PCB to fix the sub PCB to the second surface of the main PCB.

### BRIEF DESCRIPTION OF THE DRAWINGS

These and/or other aspects of the present general inventive concept will become apparent and more readily appreciated from the following description of the embodiments, taken in conjunction with the accompanying drawings of which:

FIG. 1 is a side sectional view illustrating a conventional PCB assembly;

FIG. 2 is a side sectional view illustrating a conventional PCB assembly combined by using a pin connector;

FIG. 3 is a schematic view illustrating a PCB assembly before being combined, according to an embodiment of the present general inventive concept;

FIG. 4 is a schematic view illustrating the PCB assembly of FIG. 3 after being combined;

FIGS. 5A to 5D are side sectional views illustrating a combining process of the PCB assembly of FIG. 3.

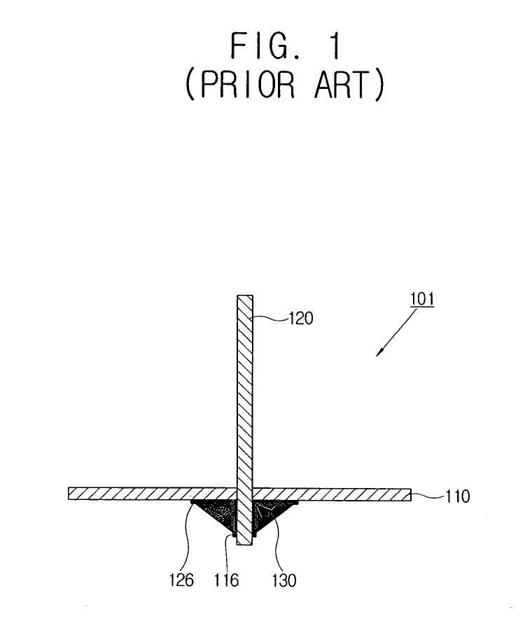

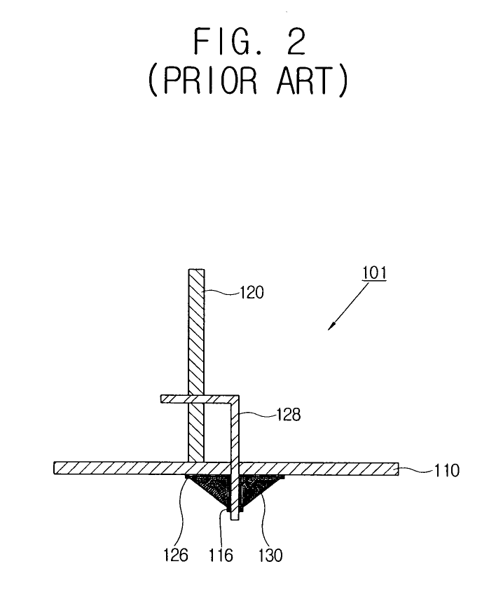

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

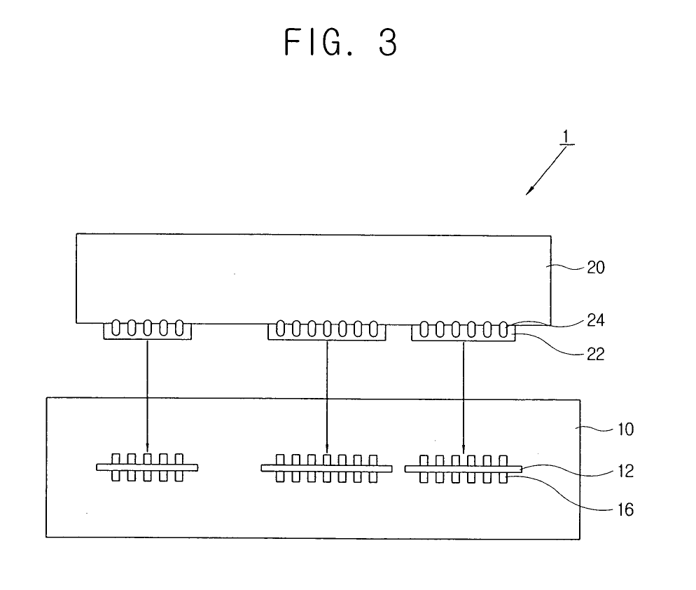

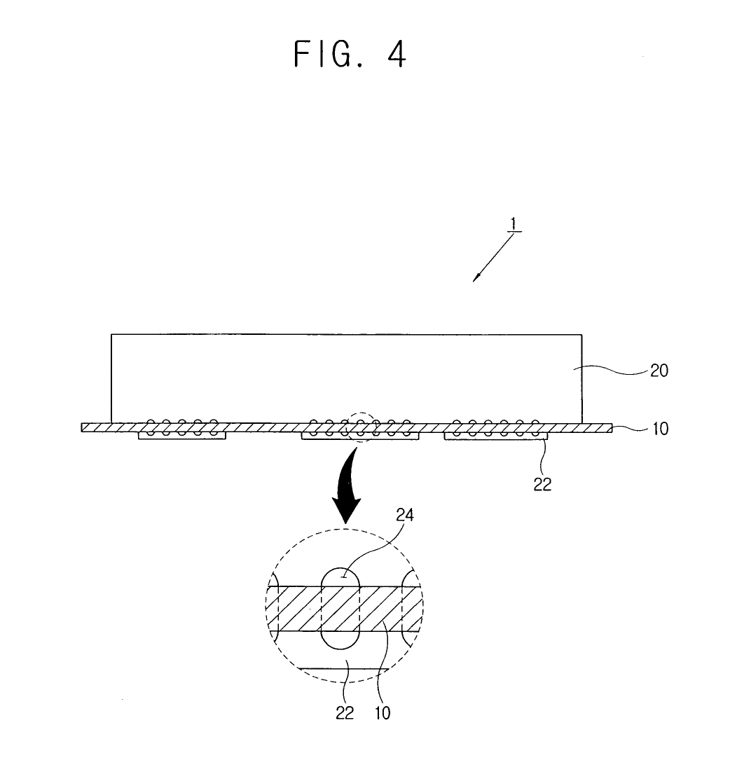

FIGS. 3 and 4 illustrate a printed circuit board (PCB) assembly 1 according to an embodiment of the present general inventive concept. Referring to FIGS. 3 and 4, the PCB assembly 1 of the present embodiment comprises a main PCB 10 and a sub PCB 20.

The main PCB 10 has at least one accommodating slit part 12 penetratingly formed through a surface thereof. A plurality of main terminal parts 16 are disposed at opposite sides of the accommodating slit part 12 along a lengthwise direction of the accommodating slit part 12. The main terminal parts 16 are disposed to align with each other on the opposite sides of the accommodating slit part 12 and on opposite surfaces of the main PCB 10, such as for example an upper surface of the main PCB 10 and a lower surface of the main PCB 10.

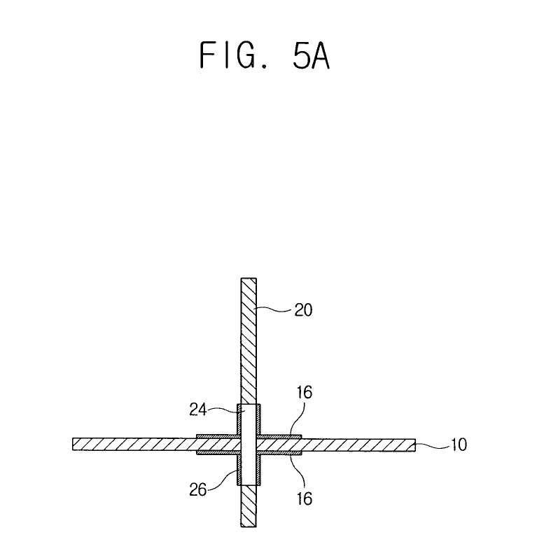

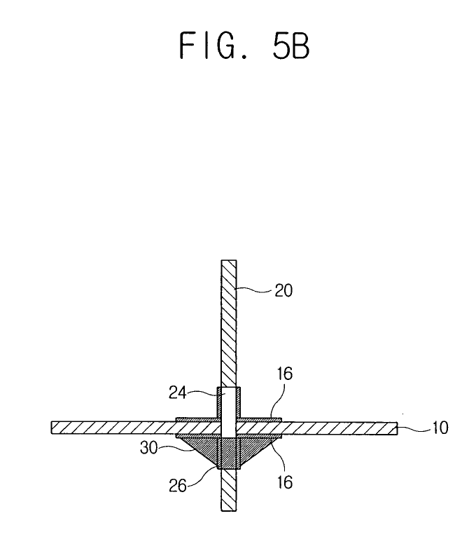

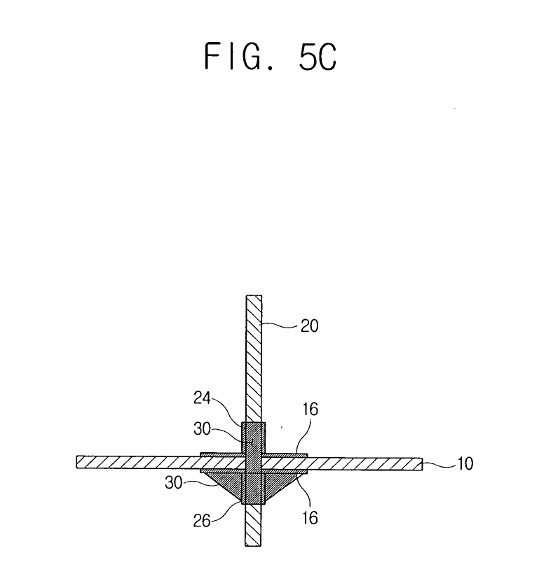

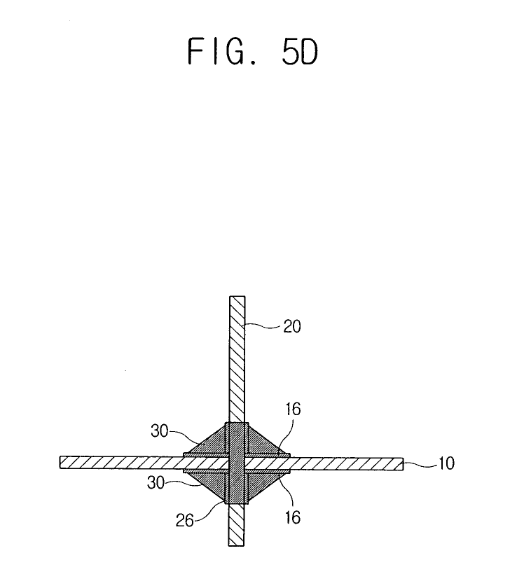

The main terminal parts 16 function as connecting terminals to electrically connect the main PCB 10 and the sub PCB 20 and also as solder-lands to allow melted soldering flux to be provided thereon to combine the sub PCB 20 with the main PCB 10. All parts of the main PCB 10 with the exception of the main terminal parts 16 can be coated to be kept clean from the melted soldering flux such that the melted soldering flux is provided only to the main terminal parts 16. A plurality of sub terminal parts 26 (see FIGS. 5A-5D) of the sub PCB 20 contact the main terminal parts 16 to electrically connect the main PCB 10 and the sub PCB 20. As illustrated in FIGS. 5A-5D, when the sub PCB 20 is combined with the main PCB 10, the main terminal parts 16 and the sub terminal parts 26 contact each other at the opposite sides of the accommodating silt part 12 and at the opposite surfaces of the main PCB 10. That is, the main terminal parts 16 and the sub terminal parts 26 contact each other such that the main PCB 10 and the sub PCB 20 are electrically connected at corner portions formed between the main PCB 10 and the sub PCB 20 when the main PCB 10 and the sub PCB 20 are combined.

At least one inserting part 22, which is insertable into the slit accommodation part 12 of the main PCB 10, is formed at a first side of the sub PCB 20. The sub PCB 20 can include plural inserting parts 22 projecting from the first side thereof to correspond to plural accommodating slit parts 12 of the main PCB 10. A through slot 24 is formed on the inserting part 22 along an inserting direction of the sub PCB 20. As illustrated in FIG. 4, the through slot 24 is longer than a thickness of the main PCB 10 and extends through the accommodating slit part 12 when the inserting part 22 is inserted into the accommodating slit part 12.

An inner portion of the through slot 24 is plated with conductive metallic material. The plated inner portion of the through slot 24 is electrically connected to the main terminal parts 16 through the sub terminal parts 26 when the sub PCB 20 is combined with the main PCB 10. The plated inner portion of the through slot 24 can also function as the sub terminal parts 26 and directly contact the main terminal parts 16 when the inserting part 22 is inserted into the slit accommodation part 12. Accordingly, the plated inner portion of the through slot 24 can also function as the solder-land at which the melted soldering flux is to be provided. The through slot 24 receives the melted soldering flux at a first surface of the main PCB 10, such as, for example, the lower surface, and the melted soldering flux travels along the through slot 24 due to a capillary phenomenon and is transferred to a second surface of the main PCB 10, such as, for example, the upper surface. Accordingly, the melted soldering flux fixes the sub PCB 20 to the main PCB 10 when the inserting part 22 is inserted into the slit accommodation part 12.

FIGS. 5A-5D illustrate a combining process of the main PCB 10 and the sub PCB 20 of the PCB assembly of FIGS. 3 and 4, according to an embodiment of the present general inventive concept.

As illustrated in FIG. 5A, the inserting part 22 (see FIG. 3) of the sub PCB 20 is inserted into the accommodating slit part 12 (see FIG. 3) of the main PCB 10. The through slot 24 formed in the inserting part 22 extends through the accommodating slit part 12 of the main PCB 10 (see FIG. 4). As illustrated in FIG. 5B, melted soldering flux 30 is then provided to the main terminal parts 16 on the first surface of the main PCB 10 to combine the main PCB 10 with the sub PCB 20. As illustrated in FIG. 5C, the melted soldering flux 30 spreads from the main terminal parts 16 on the first surface of the main PCB 10 along the through slot 24 of the sub PCB 20. As illustrated in FIG. 5D, the melted soldering flux 30 then spreads to the main terminal parts 16 on the second surface of the main PCB 10. The melted soldering flux 30 then solidifies to securely combine the main PCB 10 and the sub PCB 20 at the first and second surfaces of the main PCB 10. Accordingly, the main PCB 10 is stably fixed to the sub PCB 20.

As illustrated in FIG. 5D, the main PCB 10 and the sub PCB 20 are fixed to each other by soldering after the inserting part 22 of the sub PCB 20 is inserted into the slit accommodating part 12 of the main PCB 10 such that the main terminal parts 16 and the sub terminal part 26 function as the solder-lands and are electrically connected to each other by mutual contact.

Although in the embodiment of FIGS. 3 and 4, a plurality of inserting parts 22 are illustrated as projecting to correspond to the accommodating slit parts 12, an entire lower portion of the sub PCB 10 can alternatively be inserted into the main PCB.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A PCB assembly comprising:
a main PCB having an accommodating slit part penetratingly formed therethrough and at least one main terminal part disposed at sides of the accommodating slit part; and
a sub PCB having an inserting part which is inserted into the accommodating slit part, the sub PCB comprising at least one sub terminal part disposed to correspond to the at least one main terminal part, and a through slot formed in the inserting part along an inserting direction of the sub PCB.

2. The PCB assembly of claim 1, wherein the through slot is longer than the thickness of the main PCB, and extends through the accommodating slit part.

3. The PCB assembly of claim 1, wherein the at least one main terminal part comprises a plurality of main terminals disposed at opposite sides of the accommodating slit part on opposite surfaces of the main PCB.

4. The PCB assembly of claim 1, wherein the at least one main terminal part of the main PCB contacts the at least one sub terminal part of the sub PCB to electrically connect the main PCB and the sub PCB when the inserting part is inserted into the accommodating slit part.

5. The PCB assembly of claim 4, wherein the main PCB and the sub PCB are soldered together at a point where the at least one main terminal part contacts the at least one sub terminal part.

6. The PCB assembly of claim 1, wherein the through slot comprises a conductive inner portion to electrically connect with the at least one main terminal part through the at least one sub terminal part when the inserting part is inserted into the accommodating slit part.

7. The PCB assembly of claim 6, wherein the conductive inner portion comprises an inner surface of the through hole plated with a conductive material.

8. The PCB assembly of claim 1, wherein the through slot extends through the accommodating slit part to transfer melted soldering flux from a first side of the main PCB to a second side of the main PCB to adhere the main PCB to the sub PCB when the inserting part is inserted into the accommodating slit part.

9. The PCB assembly of claim 1, wherein the accommodating slit part comprises a plurality of accommodating slits and the inserting part comprises a plurality of inserting portions protruding to correspond to the plurality of accommodating slits.

10. The PCB assembly of claim 1, wherein the inserting part comprises a lower portion of the sub PCB having a predetermined be insertable into the accommodating slit part.

11. A printed circuit board (PCB) assembly, comprising:
a main PCB having an accommodating hole formed through first and second surfaces thereof; and
a sub PCB having an inserting portion insertable into the main PCB and one or more through holes provided through the inserting portion to transfer melted soldering flux from the first surface of the main PCB to the second surface of the main PCB when the inserting portion is inserted into the accommodating hole to fix the sub PCB to the main PCB.

12. The PCB assembly of claim 11, wherein the main PCB comprises a plurality of main terminals disposed surrounding the accommodating hole on the first and second surfaces.

13. The PCB assembly of claim 12, wherein each through hole comprises a conductive inner portion to electrically connect with one or more of the main terminals when the inserting portion is inserted into the accommodating hole.

14. The PCB assembly of claim 13, wherein the conductive inner portion of each through hole contacts the one or more of the main terminals when the inserting portion is inserted into the accommodating hole.

15. The PCB assembly of claim 13, wherein the sub PCB further comprises one or more sub terminals extending from each through hole to contact the one or more main terminals when the inserting portion is inserted into the accommodating hole.

16. The PCB assembly of claim 12, wherein the one or more through hole transfer the melted soldering flux to each of the plurality of main terminals.

17. A printed circuit board (PCB) assembly, comprising:
a main PCB having an accommodating slit formed through first and second surfaces thereof and a plurality of main terminals surrounding the accommodating slit on the first and second surfaces; and
a sub PCB insertable into the accommodating slit and having a plurality of sub terminals to form a plurality of electrical connections with the plurality of main terminals and a through hole to receive melted soldering flux at one of the electrical connections and to spread the received melted soldering flux to the remaining electrical connections to fix the sub PCB to the main PCB at each of the electrical connections.

18. A method of fixing a sub PCB to a main PCB, comprising:
inserting a portion of the sub PCB through an accommodating slit formed in the main PCB;
receiving melted soldering flux at a first surface of the main PCB to fix the sub PCB to the first surface of the main PCB; and
spreading the melted soldering flux along a through hole formed in the sub PCB to a second surface of the main PCB to fix the sub PCB to the second surface of the main PCB.

19. The method of claim 18, wherein the inserting of the portion of the sub PCB through the accommodating slit formed in the main PCB comprises:
electrically connecting the sub PCB to the main PCB at a plurality of points on the first and second surfaces of the main PCB.

20. The method of claim 19, wherein the receiving of the melted soldering flux comprises:
receiving the melted soldering flux at one of the plurality of points on the first surface of the main PCB.

21. The method of claim 20, wherein the spreading of the melted soldering flux along the through hole comprises:
spreading the melted soldering flux to all of the plurality of points on the first and second surfaces of the main PCB.
